(19) United States
(12) Patent Application Publication
(10) Pub. No.: US 2024/0265180 A1
(43) Pub. Date: Aug. 8, 2024

(54) METHOD OF EXECUTING DESIGN FLOW WITH MACHINE LEARNING TECHNIQUES

(71) Applicant: TAIWAN SEMICONDUCTOR MANUFACTURING COMPANY, LTD., Hsinchu (TW)

(72) Inventors: Ya Tung HAN, Hsinchu (TW); Huang-YU CHEN, Hsinchu (TW)

(21) Appl. No.: 18/165,292

(22) Filed: Feb. 6, 2023

(51) Int. Cl. G06F 30/3323; G06N 3/08

(52) U.S. Cl. CPC G06F 30/3323; G06N 3/08

(57) ABSTRACT

A method includes constructing a set of reference design contents associated with a set of reference design recipes. The method also includes determining a content similarity between a user design content and a reference design content taken from the set of reference design contents. The method further includes executing a design flow specified by a reference design recipe associated with the reference design content, as a result of the content similarity reaching a predetermined threshold.

### BACKGROUND

The recent trend in miniaturizing integrated circuits (ICs) has resulted in smaller devices which consume less power yet provide more functionality at higher speeds. The miniaturization process has also resulted in stricter design and manufacturing specifications as well as reliability challenges. Various electronic design automation (EDA) tools generate, optimize, and verify standard cell layout designs for integrated circuits while ensuring that the standard cell layout design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic drawing of a method of optimizing a layout design generated from design flows based on machine learning techniques, in accordance with some embodiments.

FIGS. 2A-2B are tables of content parameters in three design contents, in accordance with some embodiments.

FIG. 2C is a table of cosine similarities between the three design contents in FIGS. 2A-2B, in accordance with some embodiments.

FIG. 3 is a flowchart of a method of calculating a cosine similarity, in accordance with some embodiments.

FIGS. 4A-4C are geometric representations of the cosine similarity, in accordance with some embodiments.

FIG. 5 is a schematic drawing of a method of optimizing a layout design, in accordance with some embodiments.

FIG. 6 is a schematic drawing of a method of optimizing a layout design, in accordance with some embodiments.

FIG. 7 is a schematic drawing of a method of generating a layout design with a design flow, in accordance with some embodiments.

FIG. 8 is a schematic drawing of a method of generating layout designs with multiple design processes based on a selected machine learning model, in accordance with some embodiments.

FIG. 9 is a flowchart of a method of selecting one of the reference machine learning models as a user machine learning model to execute a user design flow, in accordance with some embodiments.

FIG. 10 is a block diagram of an electronic design automation (EDA) system in accordance with some embodiments.

FIG. 11 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below.” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

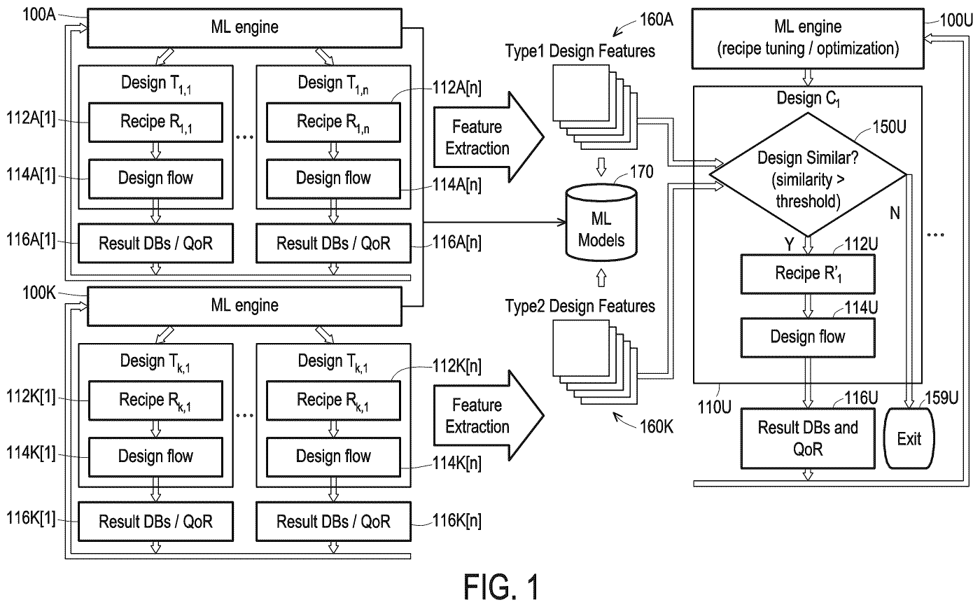

FIG. 1 is a schematic drawing of a method of optimizing a layout design generated from design flows based on machine learning techniques, in accordance with some embodiments. In some embodiments, the design flow receives a digital circuit design as the input and generates a layout design as the output. In some embodiments, the layout design generated from a design flow is in a Graphic Data System (GDS) file format (e.g., GDSII file format); that is, the layout design is a GDS layout design. In some embodiments, the digital circuit design received by the design flow is a circuit file described at the register-transfer level (RTL); that is, the digital circuit design is an RTL circuit design. The RTL circuit design is often specified in a hardware description language (HDL), such as Verilog or VHDL. A design flow that converts an RTL circuit design to a GDS layout design is an RTL-to-GDS design flow.

A design flow includes one or more operations implemented with software programs, such as, the operation of synthesis, the operation of floor planning, or the operation of automatic placement and routing. In some embodiments, the operation of logic synthesis in a design flow includes converting an RTL circuit design into gate level netlists. In some embodiments, the operation of floor planning in a design flow includes estimating the width and the height for a die size, creating IO pad sites, placing power rails, creating cell rows, and/or placing macros. In some embodiments, the operation of automatic placement and routing in a design flow includes producing a valid placement layout from a synthesized gate level netlists using standard cell fetched from libraries, while the placement layout is optimized according to various design objectives. In some embodiments, during the operation of automatic placement and routing, after the placement step, the routing step adds wires to connect properly the placed components while obeying various design rules for the integrated circuit. In some embodiments, during the operation of automatic placement and routing, the clock distribution network is also created.

In some embodiments, a design flow includes at least the operation of automatic placement and routing. In some embodiments, a design flow includes each of the operation of logic synthesis, the operation of floor planning, and the operation of automatic placement and routing. In some embodiments, a design flow also includes additional operations, such as, timing analysis, GDSII creation, and signoff.

In FIG. 1, at least some of the operations in the design flows are implemented with machine-learning techniques. For example, in some embodiments, Convolutional Neural Network (CNN), Graph Convolutional Networks (GCN), and/or Reinforcement Learning (RL) are used for classifying and generating optimal design flows. In some embodiments, GCN and/or RL are used for placement decisions. In some embodiments, support vector machine (SVM) and/or various kinds of neural networks are used to evaluate potential routing paths. In some embodiments, CNN, generative adversarial network (GAN) and/or Multivariate Adaptive Regression Splines (MARS) are used to minimize routing congestions. In some embodiments, Latent Dirichlet Allocation (LDA) and/or K-Nearest Neighbor (KNN) are used to predict wirelengths. In some embodiments, deep neural network (DNN) is used in logic synthesis to optimize the selection processes of the And-Inverter Graph (AIG) and/or the Majority-Inverter Graph (MIG).

In some embodiments, a design flow is specified by a corresponding design recipe, and the design flow is influenced by the parameters provided in the corresponding design recipe. In some embodiments, a design recipe for a design flow includes various parameters that are taken as input values or specifications by one or more operations of the design flow. For example, in some embodiments, a design recipe includes parameter values for specifying the technology that is targeted by the layout design generated from the design flow—such as, whether the layout design is designed for fin transistors or GAA transistors (i.e., Gate-All-Around transistors), or what is the targeted technology node (e.g., 5 nm node or 3 nm node) that is in the layout design. In some embodiments, a design recipe for a design flow also includes a flow script that controls the operations of the design flow. In some embodiments, when one or more operations in a design flow are implemented based on a machine-learning technique in the form of a neural network, a design recipe for the design flow includes information for specifying the neural network, such as, the node information for describing the neural network. In some embodiments, the node information is provided in a node database or a node file.

In FIG. 1, during a design process C₁, a design flow 114U is specified by a design recipe 112U. Both the design flow 114U and the design recipe 112U are coupled to a machine learning engine 100U. During the design process C₁, when the design flow 114U is carried out in a machine learning session, the design flow 114U and the design recipe 112U are subjected to some optimization processes, and some of the parameters in the design recipe 112U are further adjusted. After the design flow 114U is carried out, in operation 116U, the results obtained are stored in databases and Quality of Result (QoR) is evaluated. In some embodiments, the results obtained in operation 116U include an updated design recipe specifying an improved design flow obtained after the optimization processes in the machine learning session. In FIG. 1, after the operation 116U, if the QoR does not reach some design objectives, next iteration of a machine learning session is carried out. In some embodiments, the machine learning session involving the design flow 114U as specified by the design recipe 112U is repeated with multiple iterations, until the layout design generated by the design flow 114U is deemed to be acceptable.

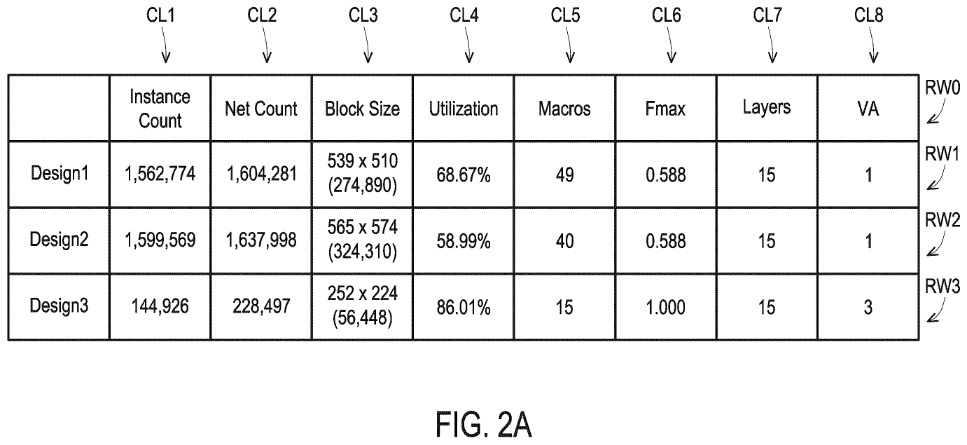

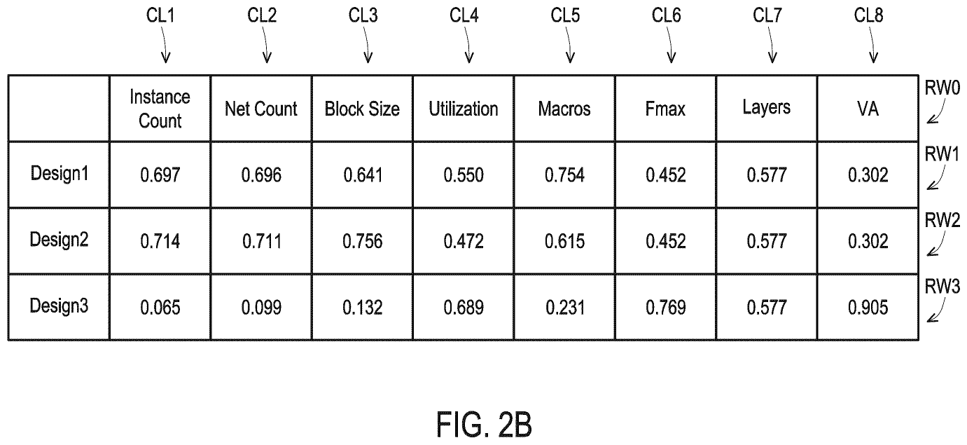

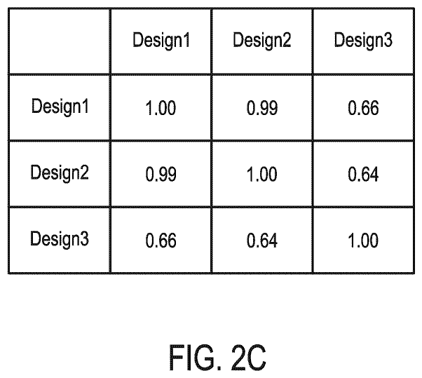

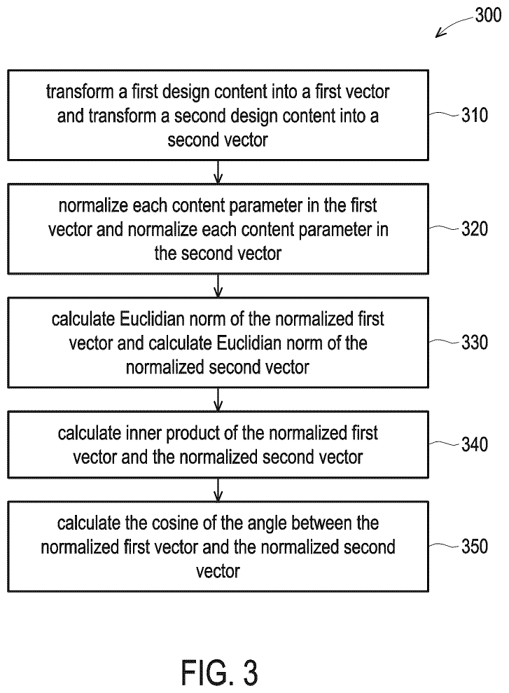

In some embodiments, whether the design flow 114U is carried out in the first interaction of a machine learning session is conditioned upon whether an initial user design recipe to be carried out by the machine learning engine 100U is similar to a reference design recipe based on a similarity comparison between two corresponding design contents (i.e., between an initial user design content associated with the initial user design recipe and a reference design content associated with the reference design recipe). At operation 150U, if a content similarity between the initial user design content and the reference design content is larger than a predetermined threshold, the design flow 114U specified by the design recipe 112U is carried out, which is followed by operation 116U. On the other hand, if the content similarity between the initial user design content and the reference design content is not larger than the predetermined threshold, the design process C₁ terminates at the exit operation 159U. An example definition of the content similarity and an example comparison of the content similarity are described with reference to FIGS. 2A-2C and FIG. 3.

In FIG. 1, the initial user design content used for the content similarity comparison at operation 150U is obtained from an initial user design recipe that is provided to the machine learning engine 100U at a user site, while the reference design content used for the content similarity comparison at operation 150U is obtained from a reference design recipe that is generated from one of the machine learning engines (e.g., 100A . . . , and 100K) at a reference site.

In some embodiments, the initial user design content includes one or more content parameters which specify the technology that the design flow 114U is targeted for, and the reference design content includes one or more content parameters which specify the technology that a reference design flow associated with the reference design content is targeted for. For example, in some embodiments, each of the initial user design content and the reference design content includes a content parameter which specifies whether the corresponding reference design flow is targeted for a fabrication process with fin transistors or a fabrication process with GAA transistors (i.e., Gate-All-Around transistors). As another example, in some embodiments, each of the initial user design content and the reference design content includes a content parameter which specifies whether the corresponding reference design flow is targeted for a 7 nm node, a 5 nm node, a 3 nm node, or 2 nm node.

In some embodiments, the initial user design content includes one or more design recipe parameters which are parameters taken from the design recipe 112U that specifies the design flow 114U, and the reference design content includes one or more design recipe parameters which are parameters taken from a reference design recipe configured to specify a corresponding reference design flow. In some embodiments, as design recipe parameters, the parameters taken from a given design recipe are parameters configured to specify the technology targeted by the design flow associated with the given design recipe. In some embodiments, as design recipe parameters, the parameters taken from a given design recipe are parameters configured to specify the machine-learning techniques used in one or more operations in the design flow associated with the given design recipe.

In some embodiments, each of the initial user design content and the reference design content includes one or more content parameters associated the layout design generated by the corresponding design flow. In an example as shown in FIGS. 2A-2B, each of the design contents Desgin1, Design2, and Design3 (listed correspondingly in rows RW1, RW2, and RW3) includes values of the content parameters identified in row RW0. Specifically, each of the design contents in rows RW1, RW2, and RW3 in FIGS. 2A-2B include the values of the following content parameters related to layout designs: instance count, net count, block size, utilization rate, number of macros, functional maximum frequency (“Fmax”), number of layers, and number of voltage areas (“VAs”).

In FIG. 1, the initial user design content and the reference design content used for the content similarity comparison at operation 150U are obtained from different sources. While the initial user design content is obtained from the initial user design recipe at the user site, the reference design content is fetched from a machine learning database 170. The machine learning database 170 includes multiple reference design contents that are obtained from design features 160A and 160K. The design features 160A is extracted from the results of the design processes carried out by the machine learning engine 100A, while the design features 160K is extracted from the results of the design processes carried out by the machine learning engine 100K. In some embodiments, the machine learning database 170 also includes reference design contents obtained from design features that are extracted from the results of the design processes carried out by additional machine learning engines.

In FIG. 1, multiple design processes (e.g., T_{1,1}, . . . , and T_{1,n}) are carried out by the machine learning engine 100A, and multiple design processes (e.g., T_{k,1}, . . . , and T_{k,n}) are carried out by the machine learning engine 100K. In some embodiments, there are additional machine learning engines (such as, 100B, 100C, . . . , which are not shown in the figure) that are configured to carry out more design processes.

Each of the multiple design processes (e.g., T_{1,1}, . . . , or T_{1,n}) carried out by the machine learning engine 100A includes a design flow which is specified by a corresponding design recipe, followed by an operation which performs data storage and QoR evaluation. For example, the design process T_{1,1} process include a design flow 114A[1] which is specified by a design recipe 112A[1], and the design process T_{1,n} process include a design flow 114A[n] which is specified by a design recipe 112A[n]. In each of the multiple design processes, in an operation after the design flow is carried out, the results obtained are stored and the QoR is evaluated; then, if the QoR does not meet the design objectives, next iteration of a machine learning session is carried out. For example, in operation 116A[1] of the design process T_{1,1}, the results obtained from the design flow 114A[1] are stored in databases and the QoR is evaluated; if the QoR indicates the need for further optimization, next iteration of a machine learning session of the design process T_{1,1} is carried out by the machine learning engine 100A. In operation 116A[n] of the design process Tin, the results obtained from the design flow 114A[n] are stored in databases and the QoR is evaluated; if the QoR indicates the need for further optimization, next iteration of a machine learning session of the design process T_{1,n} is carried out by the machine learning engine 100A.

Similarly, each of the multiple design processes (e.g., T_{k,1}, . . . , or T_{k,n}) carried out by the machine learning engine 100K includes a design flow which is specified by a corresponding design recipe, followed by an operation which performs data storage and QoR evaluation. For example, the design process T_{k,1} includes a design flow 114K[1] which is specified by a design recipe 112K[1], and includes operation 116K[1] after the design flow 114K[1] performs data storage and QoR evaluation. Further iteration of a machine learning session of the design process T_{k,1} is carried out by the machine learning engine 100K after QoR evaluation in operation 116K[1]. The design process T_{k,n} includes a design flow 114K[n] which is specified by a design recipe 112K[n], and includes operation 116K[n] after the design flow 114K[n] performs data storage and QoR evaluation. Further iteration of a machine learning session of the design process T_{k,n} is carried out by the machine learning engine 100K after QoR evaluation in operation 116K[n].

In FIG. 1, features are extracted from the results of the design processes carried out by the machine learning engines 100A and 100K, and the extracted design features 160A and 160K are saved in the machine learning database 170. In some embodiments, the extracted features are fetched from the machine learning database 170 and used as references by another machine learning engine (such as the machine learning engine 100U).

In some embodiments, reference design contents are constructed based the design features extracted from the results of the design processes carried out by the machine learning engines 100A and 100K. In some embodiments, each of the multiple design processes (e.g., T_{1,1} or T_{1,n}) carried out by the machine learning engine 100A is associated with a corresponding design content constructed based on the extracted design features 160A, and each of the multiple design processes (e.g., T_{k,1} or T_{k,n}) carried out by the machine learning engine 100K is associated with a corresponding design content constructed based on the extracted design features 160K. The design contents constructed based on the extracted design features 160A and 160K are stored in the machine learning database 170 as a set of reference design contents.

During the design process C₁, an initial user design content is provided to a machine learning engine 100U at the user site, and a reference design content is taken from the set of reference design contents in the machine learning database 170. At operation 150U, the initial user design content and the reference design content are compared for content similarity. The reference design content used in operation 150U is associated with one of the design recipes used in the design processes which are carried out by the machine learning engines (100A, . . . , and 100K) at the reference site. If the content similarity between the initial user design content and the reference design content reaches a predetermined threshold, the reference design recipe associated with the reference design content is used as the design recipe 112U, and the corresponding design flow 114U specified by the reference design recipe is carried out by the machine learning engine 100U.

In some embodiments, the content similarity used for comparing the initial user design content and the reference design content is implemented based on one or more of the following example techniques: One-Hot Encoding, Bag of Words, TF-IDF, word2vec, and auto encoder. In some embodiments, the content similarity used for comparing the initial user design content and the reference design content is a cosine similarity. FIGS. 2A-2B are tables of content parameters in three design contents, in accordance with some embodiments. FIG. 2C is a table of cosine similarities between the three design contents in FIGS. 2A-2B, in accordance with some embodiments.

In the tables of FIGS. 2A-2B, the content parameters of three design contents Design1, Design2, and Design3 are listed correspondingly in rows RW1, RW2, and RW3. The names of the content parameters are listed in row RW0. The values of the content parameters in the three design contents are listed in the eight columns (i.e., CL1-CL8) of the tables, and the eight columns (i.e., CL1-CL8) are correspondingly specified by the following content parameter names: instance count, net count, block size, utilization rate, number of macros, functional maximum frequency (“Fmax”), number of layers, and number of voltage areas (“VAs”).

In an example embodiment, values of the content parameters are taken from the layout designs generated from the design processes associated with the three design contents. The values of the content parameters that are taken from the layout designs are list directly in the table of FIG. 2A as raw values of the content parameters, the raw values of the content parameters in the table of FIG. 2A are normalized for each column, and the normalized content parameters are listed in the table of FIG. 2B.

The raw value of a content parameter is normalized based on a range of the content parameter in the corresponding column. For example, the raw values of the Block Size for design contents Design1, Design2, and Design3 are correspondingly equal to 274,890, 324,310, and 56,488, as listed in column CL3 of the table in FIG. 2A. The normalized values of the Block Size for design contents Design1, Design2, and Design3 are correspondingly equal to 0.641, 0.756, and 0.132, as listed in column CL3 of the table in FIG. 2B. Here, to obtain the normalized values of the Block Size, each of the raw values (such as, 274,890, 324,310, and 56,488) is divided by a normalization factor (which is the square root of 274,890²+324,310²+56,488²).

The cosine similarities between the three design contents (Design1, Design2, and Design3) are calculated based on the values of the normalized content parameters listed in FIG. 2B. The results of the calculation for the cosine similarities are listed in the table of FIG. 2C. As shown in the table of FIG. 2C, the cosine similarity between the design contents Design1 and Design2 is 0.99, the cosine similarity between the design contents Design1 and Design3 is 0.66, and the cosine similarity between the design contents Design2 and Design3 is 0.64. One example method of calculating a cosine similarity between two design contents is shown in FIG. 3.

FIG. 3 is a flowchart of a method 300 of calculating a cosine similarity between a first design content and a second design content, in accordance with some embodiments. The sequence in which the operations of method 300 are depicted in FIG. 3 is for illustration only; the operations of method 300 are capable of being executed in sequences that differ from that depicted in FIG. 3. It is understood that additional operations may be performed before, during, and/or after the method 300 depicted in FIG. 3, and that some other processes may only be briefly described herein.

In operation 310 of method 300, the first design content and the second design content are correspondingly transformed into a first vector and a second vector. In the example as shown in FIG. 2A, each of the design contents (Design1, Design2, and Design3) is transferred into a vector in the eight-dimension space. The values of eight content parameters in a design content are the eight components of the vector corresponding to the design content. For example, the design content Design1 is transformed into a first vector having eight components listed in columns CL1-CL8 of the row RW1, and the design content Design2 is transformed into a second vector having eight components listed in columns CL1-CL8 of the row RW2.

In operation 320 of method 300, content parameters in the first vector and content parameters in the second vector are normalized. In the example as shown in FIGS. 2A-2B, the values of the content parameters in each of the eight columns is normalized independently. In the table of FIG. 2B, the eight normalized components of the normalized first vector are listed in columns CL1-CL8 of the row RW1, and the eight normalized components of the normalized second vector are listed in columns CL1-CL8 of the row RW2.

In operation 330 of method 300, Euclidian norm of the normalized first vector and Euclidian norm of the normalized second vector are calculated. For example, in FIG. 2B, the squares of each of the eight normalized components in the row RW1 are added together as a first sum value, and the square root of the first sum value is the Euclidian norm of the normalized first vector. In FIG. 2B, the squares of each of the eight normalized components in the row RW2 are added together as a second sum value, and the square root of the second sum value is the Euclidian norm of the normalized second vector.

In operation 340 of method 300, inner product of the normalized first vector and the normalized second vector are calculated. In example of FIG. 2B, the normalized component of each column (e.g., CL1) in the row RW1 is multiplied with the corresponding normalized component of the same column (e.g., CL1) in the row RW2 to obtain a multiplication result of a single column. When the multiplication results of all eight columns (i.e., CL1-CL8) are added together, the summation of the eight terms is the inner product of the normalized first vector and the normalized second vector.

In operation 350 of method 300, the cosine of the angle between the normalized first vector and the normalized second vector are calculated. In some embodiments, the inner product of the normalized first vector and the normalized second vector (which is obtained in operation 340) is divided by the product of Euclidian norm of the normalized first vector and Euclidian norm of the normalized second vector (which are obtained in operation 330). The cosine of the angle between the normalized first vector and the normalized second vector is defined as the cosine similarity between the first design content and the second design content. In general, the cosine similarity between the first design content and the second design content is calculated based on following equation:

$$similarity ( A , B ) = cos ( θ ) = \frac{A \cdot B}{‖ A ‖ ‖ B ‖} = \frac{{\sum }_{i = 1}^{n} {A}_{i} \times {B}_{i}}{\sqrt{{\sum }_{i = 1}^{n} {( {A}_{i} )}^{2}} \times \sqrt{{\sum }_{i = 1}^{n} {( {B}_{i} )}^{2}}}$$

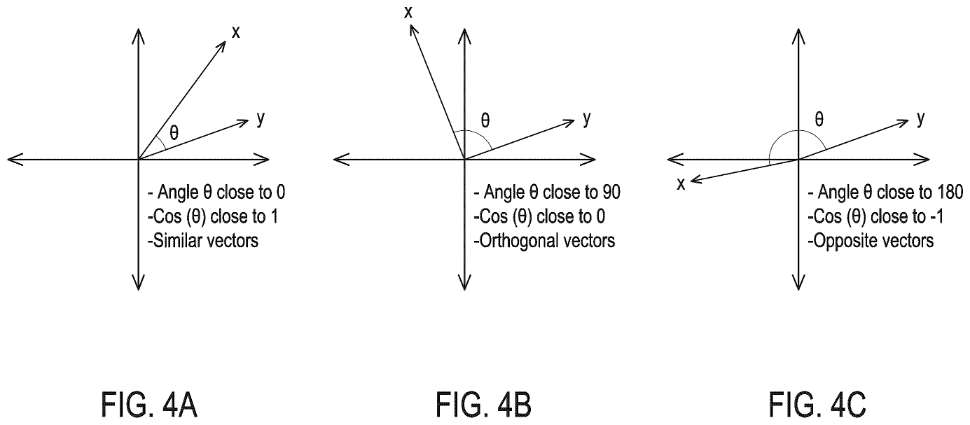

FIGS. 4A-4C are geometric representations of the cosine similarity between a first design content and a second design content, in accordance with some embodiments. In FIG. 4A, as the angle θ between the two vectors is close to 0 degree, the cosine of the angle θ is close to 1.0, and the cosine similarity between the first design content and the second design content is close to 1.0. In FIG. 4B, as the angle θ between the two vectors is close to 90 degrees, the cosine of the angle θ is close to 0.0, and the cosine similarity between the first design content and the second design content is close to 0.0. In FIG. 4C, as the angle θ between the two vectors is close to 180 degrees, the cosine of the angle θ is close to −1.0, and the cosine similarity between the first design content and the second design content is close to −1.0.

In the example embodiments of FIG. 1, content similarity is compared between an initial user design content at the user site and one of the reference design contents stored in the machine learning database 170 which are constructed based on the extracted design features 160A and 160K. The design features 160A and 160K are extracted from the results of the design processes carried out by the machine learning engines 100A and 100K. In some embodiments, the machine learning model used in the machine learning engine 100U at the user site is different from the machine learning model used in the machine learning engine 100A or 100K at the reference site. Sometimes, the machine learning models used in the machine learning engines 100A and 100K may not always be the same or may subject to change for variety of reasons. Therefore, in some embodiments, the machine learning model in the machine learning engine at the reference site that is used to generate the design feature (such as, 160A or 160K) is also provided to the machine learning engine 100U at the user site.

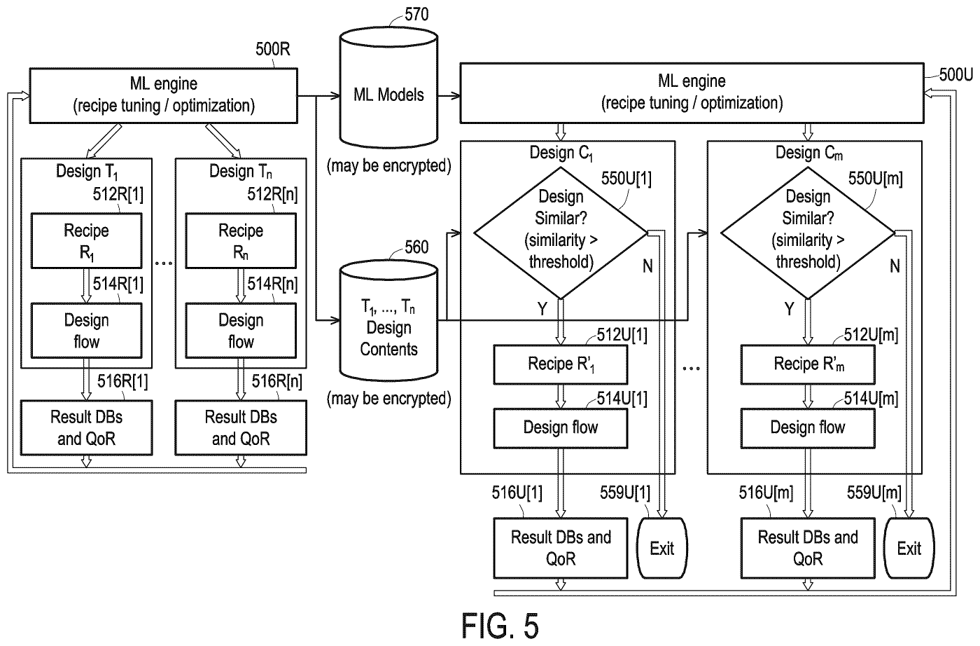

FIG. 5 is a schematic drawing of a method of optimizing a layout design at a user site based on a reference design content and a reference machine learning model provided by a reference site, in accordance with some embodiments. In FIG. 5, multiple design processes (e.g., T₁, . . . , and Tₙ) are carried out by the reference machine learning engine 500R at a reference site based on one or more reference machine learning models. Each reference machine learning model is associated with one or more of the multiple design processes (e.g., T₁, . . . , or Tₙ). Each of the multiple design processes (e.g., T₁, . . . , or Tₙ) includes a design flow which is specified by a corresponding design recipe. For example, the design process T₁ process include a design flow 514R[1] which is specified by a design recipe 512R[1], and the design process In process include a design flow 514R[n] which is specified by a design recipe 512R[n].

In each of the multiple design processes, after the operation following the design flow is carried out, the results obtained are stored and QoR is evaluated. For example, in operation 516R[1] of the design process T₁, the results obtained from the design flow 514R[1] are stored in databases, and after QoR is evaluated; if the evaluated QoR fails to meet design objectives, further iteration of a machine learning session of the design process T₁ can be carried out by the reference machine learning engine 500R. In operation 516R[n] of the design process Tₙ, the results obtained from the design flow 514R[n] are stored in databases, and after QoR is evaluated; if the evaluated QoR fails to meet design objectives, further iteration of a machine learning session of the design process Tₙ can be carried out by the reference machine learning engine 500R.

In FIG. 5, the multiple reference design contents are constructed from the multiple design processes (T₁, . . . , and Tₙ). In some embodiments, a reference design content is constructed from each of the multiple design processes (T₁, . . . , and Tₙ). In some embodiments, the reference design content constructed from a selected design process (e.g., T₁, . . . , or Tₙ) includes one or more content parameters which specify the technology targeted by the design flow of the selected design process. In some embodiments, the reference design content constructed from a selected design process (e.g., T₁, . . . , or Tₙ) includes one or more content parameters associated the layout design generated by the design flow of the selected design process. In some embodiments, the reference design content constructed from a selected design process (e.g., T₁, . . . , or Tₙ) includes one or more design recipe parameters in the design recipe of the selected design process.

In FIG. 5, a design flow (e.g., 512R[1]) in a design process (e.g., T1) is executed based on a reference machine learning model associated with the design process (e.g., T1). In some embodiments, the reference machine learning model associated with a design process includes one or more specific machine learning models used in the design flow of the design process. For example, when a neural network (such as CNN or GCN) is used in the design flow (e.g., 512R[1]) of a design process (e.g., T1), some implementations of the reference machine learning model associated with the design process (e.g., T1) include the specific machine learning model describing the neural network (such as CNN or GCN) used in the design flow (e.g., 512R[1]).

In some embodiments, the reference machine learning model associated with a design process includes one or more model parameters for the specific machine learning techniques used in the design flow of the design process. For example, when clustering techniques (e.g., LDA or KNN) are used to predict wirelengths in a layout design generated during the design flow (e.g., 512R[1]) of a design process (e.g., T1), some implementations of the reference machine learning model associated with the design process (e.g., T1) include one or more model parameters used by the clustering techniques (e.g., LDA or KNN). For example, in some embodiments, the model parameters used with the KNN techniques include the number k for characterizing nearest neighbors and/or the distance metric (e.g., Euclidean distance, or Hamming distance) for measuring the distance between the objects of interests.

In FIG. 5, the reference machine learning models used in the reference machine learning engine 500R are stored in a machine learning model database 570, and the multiple reference design contents constructed from the multiple design processes are stored in a design content database 560.

In FIG. 5, an user machine learning engine 500U is coupled to the machine learning model database 570 stored with various reference machine learning models. The user machine learning engine 500U uses one or more of the reference machine learning models to carry out multiple design processes (e.g., C₁, . . . , and Cₘ). Each of the multiple design processes (e.g., C₁, . . . , or Cₘ) is associated with a user machine learning model which is the same as one of the reference machine learning models fetched from the machine learning model database 570. Each of the multiple design processes (e.g., C₁, . . . , or Cₘ) includes a design flow which is specified by a corresponding design recipe. For example, the design process C₁ process include a design flow 514U[1] which is specified by a design recipe 512U[1], and the design process Cₘ process include a design flow 514U[m] which is specified by a design recipe 512U[m].

In each of the multiple design processes (e.g., C₁, . . . , or Cₘ), in the operation after the design flow is carried out, the results obtained are stored and QoR is evaluated. For example, in operation 516U[1] of the design process C₁, the results obtained from the design flow 514U[1] are stored in databases and QoR is evaluated; in the event that the evaluated QoR fails to meet design objectives, further iteration of a machine learning session of the design process C₁ can be carried out by the user machine learning engine 500U. In operation 516U[m] of the design process Cₘ, the results obtained from the design flow 514U[m] are stored in databases and QoR is evaluated; in the event that the evaluated QoR fails to meet design objectives, further iteration of a machine learning session of the design process Cₘ can be carried out by the user machine learning engine 500U.

In some embodiments, whether the design flow in a design process (e.g., C₁, . . . , or Cₘ) is carried out in the first interaction of a machine learning session is conditioned upon whether an initial user design recipe provided to the user machine learning engine 500U is similar to a reference design recipe, based upon a similarity comparison between two corresponding design contents (i.e., between an initial user design content associated with the initial user design recipe and a reference design content associated with the reference design recipe). For example, in the design process C₁, at operation 550U[1], if a content similarity between the initial user design content for the design process C₁ and the reference design content fetched from the design content database 560 is larger than a predetermined threshold, the design flow 514U[1] specified by the design recipe 512U[1] is carried out and followed by operation 516U[1]. On the other hand, if the content similarity between the initial user design content and the reference design content is not larger than the predetermined threshold, the design process C₁ terminates at the exit operation 559U[1].

Similarly, in the design process Cₘ, at operation 550U[m], if a content similarity between the initial user design content for the design process Cₘ and the reference design content fetched from the design content database 560 is larger than a predetermined threshold, the design flow 514U[m] specified by the design recipe 512U[m] is carried out and followed by operation 516U[m]. On the other hand, if the content similarity between the initial user design content and the reference design content is not larger than the predetermined threshold, the design process Cₘ terminates at the exit operation 559U[m].

In some alternative embodiments different from that in FIG. 5, each reference design content and the reference machine learning model (associated with the reference design content) are stored in a same database.

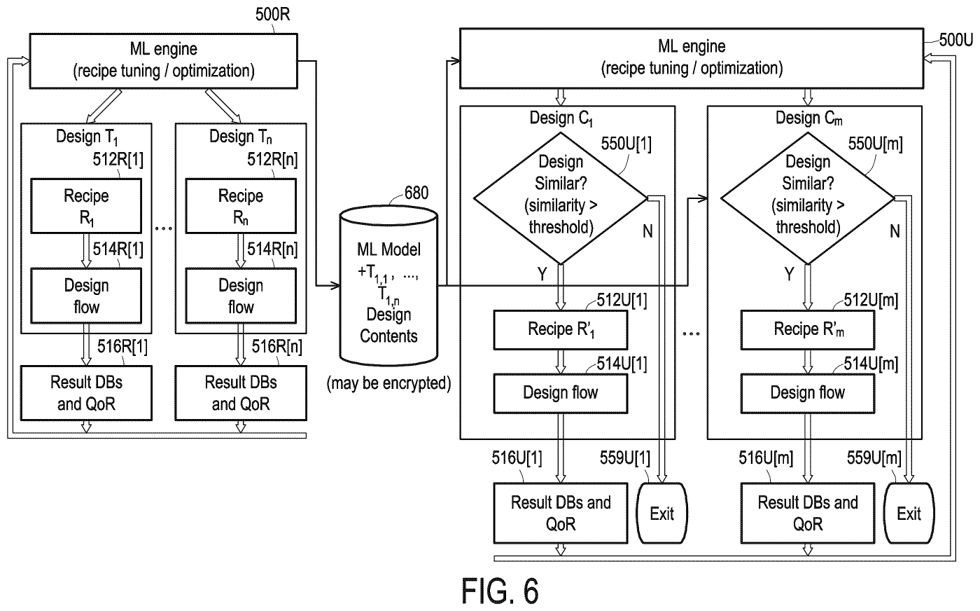

FIG. 6 is a schematic drawing of a method of optimizing a layout design that includes fetching a reference design content and the associated reference machine learning model from a design content database, in accordance with some embodiments. The embodiment in FIG. 6 is modified from the embodiment in FIG. 5. The modification includes substituting both the machine learning model database 570 and the design content database 560 with a machine learning content database 680.

During the operation process, when a reference design content DTx is constructed for a design process Tₓ, which is one of the multiple design processes (e.g., T₁, . . . , or Tₙ) carried out by the reference machine learning engine 500R, the machine learning model MTx associated with the design process Tₓ is paired with the reference design content DTx as the corresponding reference machine learning model (associated with the reference design content DTx). Thereafter, the reference design content DTx and the associated reference machine learning model MTx are stored in the machine learning content database 680 as a pair of related data.

In some embodiments, a reference machine learning model MTx is fetched from the machine learning content database 680 and loaded into the user machine learning engine 500U. For each design process Cᵢ (with 1≤i≤m) carried out based on the reference machine learning model MTx, a content similarity is tested between an initial user design content for the design process Cᵢ and a reference design content that is fetched from the design content database 680. As an example, when the design process C₁ is carried out based on the reference machine learning model MTx, a content similarity is tested at operation 550U[1] before the design flow 514U[1] specified by the design recipe 512U[1] is carried out. When the design process Cₘ is carried out based on the reference machine learning model MTx, a content similarity is tested at operation 550U[m] before the design flow 514U[m] specified by the design recipe 512U[m] is carried out.

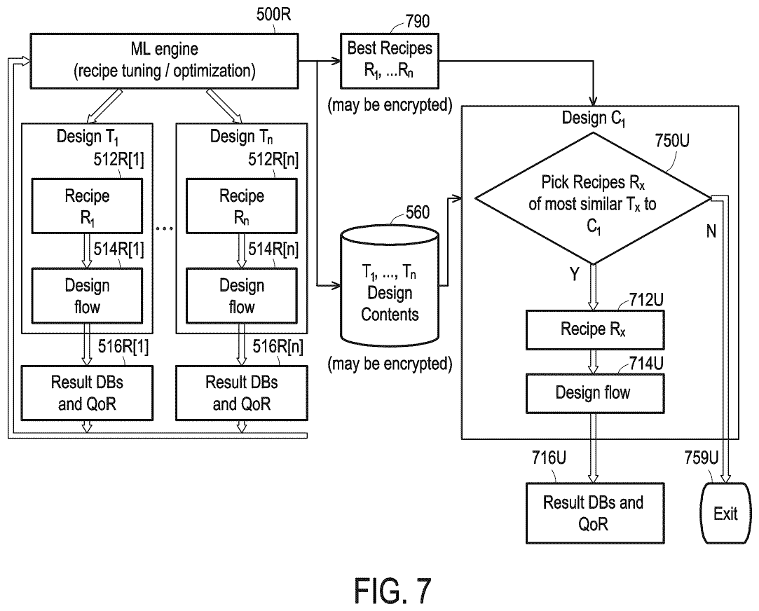

In some embodiments such as the embodiments in FIG. 7, reference design contents are fetched from a design content database. Based on similarity comparisons with the reference design contents, one design recipe is selected from multiple reference design recipes) as the user design recipe, and the design flow specified by the user design recipe is used to generate user layout designs.

FIG. 7 is a schematic drawing of a method of generating a layout design with a design flow that is specified by a user design recipe selected from multiple reference design recipes, in accordance with some embodiments. In FIG. 7, multiple design processes (e.g., T₁, . . . , and Tₙ) are carried out by the reference machine learning engine 500R at a reference site based on one or more reference machine learning models. The implementation of the multiple design processes (e.g., T₁, . . . , and Tₙ) in FIG. 7 is similar to the implementation as shown in FIG. 5. Each reference machine learning model is associated with one or more of the multiple design processes (e.g., T₁, . . . , or Tₙ). Each of the multiple design processes (e.g., T₁, . . . , or Tₙ) includes a design flow which is specified by a corresponding design recipe.

The embodiment in FIG. 7 is modified from the embodiment in FIG. 5. The modification includes substituting the machine learning model database 570 with a design recipe database 790. The modification also includes changing the implementation of the user design process C₁. In FIG. 7, some of the reference design recipes used to specify the design flows in the multiple design processes (e.g., T₁, . . . , or Tₙ) are stored in a design recipe database 790 as the reference design recipes (R₁, . . . , and Rₙ). In FIG. 7, a user design process C₁ having a design flow 714U is carried out to generate a layout design. The design flow 714U is specified by a design recipe 712U which is selected from one of the reference design recipes (R₁, . . . , and Rₙ) in the design recipe database 790. During operation 716U of the user design process C₁, the results obtained from the design flow 714U are stored in databases and Quality of Result (QoR) is evaluated.

In FIG. 7, a reference design recipe Rₓ is selected as the design recipe 712U based on values of content similarities. In some embodiments, the reference design recipe Rₓ is selected because a design content of the reference design recipe Rₓ is most similar to the user design content corresponding to the user design process C₁. Specifically, the reference design recipes (R₁, . . . , and Rₙ) are fetched from the design recipe database 790, and the reference design contents for the design process (T₁, . . . , and Tₙ) are fetched from the design content database 560. Each of the reference design recipes (R₁, . . . , and Rₙ) and a corresponding reference design content are associated with a common reference design process (e.g., T₁, . . . , or Tₙ).

For each of the reference design recipes (R₁, . . . , and Rₙ), the corresponding reference design content is identified based on the common reference design process, and a content similarity between the corresponding reference design content and the user design content is calculated for similarity comparison. The reference design recipe Rₓ having a corresponding reference design content that is most similar to the user design content is determined based on the calculated content similarities. When cosine content similarity is used as the content similarity for the similarity comparison, The reference design content DRₓ₁ (of a first reference design recipe Rₓ₁) is more similar to the user design content than the reference design content DRₓ₂ (of a second reference design recipe Rₓ₂), if the cosine content similarity cos (θ₁) calculated for the first reference design recipe Rₓ₁ is larger than the cosine content similarity cos (θ₂) calculated for the second reference design recipe Rₓ₂.

In operation 750U of In FIG. 7, if a reference design recipe (e.g., R₁, . . . , or Rₙ) is not the reference design recipe Rₓ having the corresponding design content DRₓ that is most similar to the user design content, the design process C₁ terminates at the exit operation 759U. On the other hand, if a reference design recipe is the reference design recipe Rₓ having the corresponding design content DRₓ that is most similar to the user design content, then, the design process C₁ uses the reference design recipe Rₓ as the user design recipe 712U, the design flow 714U as specified by the design recipe 712U is carried out to generate a layout design. Then, in operation 716U, the results are stored in databases and Quality of Result (QoR) is evaluated.

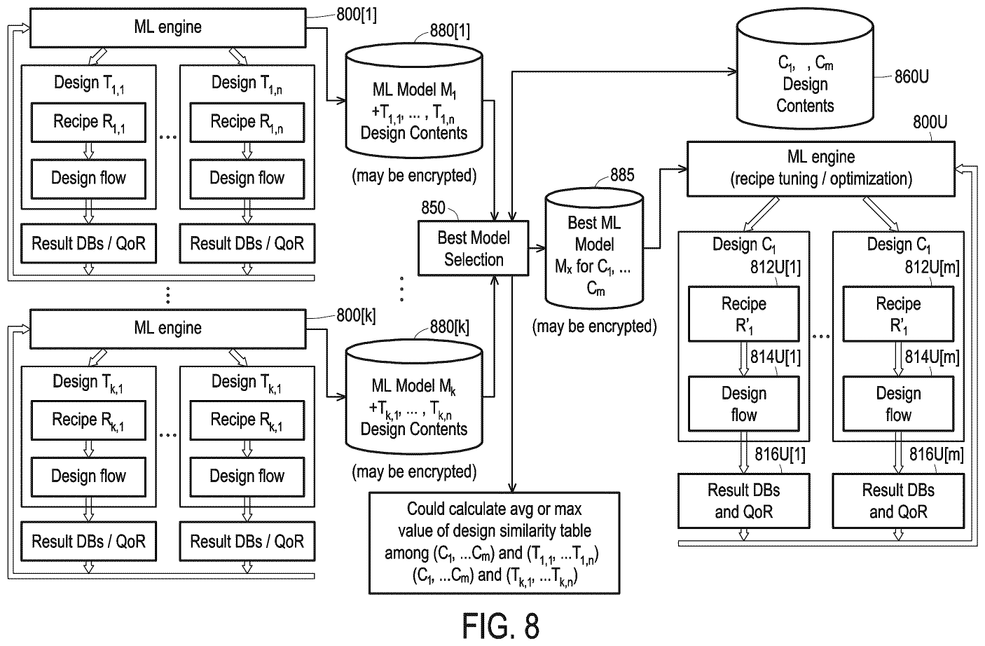

In some embodiments such as the embodiments in FIG. 8, multiple reference machine leaning models are used in reference machine learning engines. One of the reference machine leaning models is selected as a selected machine leaning model, and the selected machine leaning model is used in multiple design processes carried out in a user machine learning engine.

FIG. 8 is a schematic drawing of a method of generating layout designs with multiple design processes based on a selected machine learning model fetched from a machine learning selected-model database, in accordance with some embodiments. In FIG. 8, the machine learning engine 800[1], the machine learning engine 800[k], and some additional machine learning engines (such as, 800[2], 800[3], . . . , which are not shown in the figure) are used as reference machine learning engines. Each of the reference machine learning engines is associated with a corresponding machine learning content database. For example, the machine learning engine 800[1] is associated with a machine learning content database 880[1], and the machine learning engine 800[k] is associated with a machine learning content database 880[k].

Each of the reference machine learning engines is configured to carry out multiple design processes based on a corresponding reference machine learning model, and each of the multiple design processes is associated with a corresponding design content, which is stored in a corresponding machine learning content database along with the corresponding reference machine learning model. For example, the machine learning engine 800[1] is configured to carry out multiple design processes (such as T_{1,1}, . . . , and T_{1,n}) based on a reference machine learning model M₁. Here, each of the multiple the design processes (e.g., T_{1,1}, . . . , or T_{1,n}) is associated with a corresponding design content, which is stored in the machine learning content database 880[1] along with the reference machine learning model M₁. Similarly, the machine learning engine 800[k] is configured to carry out multiple design processes such as T_{k,1}, . . . , and T_{k,n} based on a reference machine learning model Mₖ. Here, each of the multiple the design processes (e.g., T_{k,1}, . . . , or T_{k,n}) is associated with a corresponding design content, which is stored in the machine learning content database 880[k] along with the reference machine learning model Mₖ.

In FIG. 8, at operation 850, one machine leaning model Mₓ is selected from the multiple reference machine leaning models (e.g., M₁, . . . , and Mₖ) as the selected machine leaning model, which is stored in a machine learning selected-model database 885. A user machine learning engine 800U is configured to carry out multiple design processes (such as C₁, . . . , and Cₘ) based on the selected machine leaning model Mₓ fetched from the machine learning selected-model database 885. Each of the multiple design processes (e.g., C₁, . . . , or Cₘ) includes a design flow which is specified by a corresponding design recipe. For example, the design process C₁ process include a design flow 814U[1] which is specified by a design recipe 812U[1], and the design process Cₘ process include a design flow 814U[m] which is specified by a design recipe 812U[m].

In each of the multiple design processes (e.g., C₁, . . . , or Cₘ), in the operation after the design flow is carried out, the results obtained are stored and QoR is evaluated. For example, in operation 816U[1] of the design process C₁, the results obtained from the design flow 814U[1] are stored in databases and QoR is evaluated; in the event that the evaluated QoR fails to meet design objectives, further iteration of a machine learning session of the design process C₁ can be carried out by the user machine learning engine 800U. In operation 816U[m] of the design process Cₘ, the results obtained from the design flow 814U[m] are stored in databases and QoR is evaluated; in the event that the evaluated QoR fails to meet design objectives, further iteration of a machine learning session of the design process Cₘ can be carried out by the user machine learning engine 800U.

In FIG. 8, each of the multiple user design processes (e.g., C₁, . . . , and Cₘ) is associated with a corresponding user design content, which is stored in a user design content database 860U.

At operation 850, the selection of the machine leaning model Mₓ depends upon the user design contents associated with the multiple user design processes (e.g., C₁, . . . , and Cₘ). In some embodiments, the user design contents associated with the multiple user design processes (e.g., C₁, . . . , and Cₘ) are fetched from the user design content database 860U, and the reference design contents for each of the machine learning models (M₁, . . . , and Mₖ) are fetched from a corresponding machine learning content database (880[1], . . . , or 880[K]).

At operation 850, for each machine learning model Mₛ (with 1≤s≤k) selected from the machine learning models (M₁, . . . , and Mₖ), a design similarity table DST[Mₛ] between the reference design contents (related to the machine learning model Mₛ) and the user design contents is calculated. Then, an average similarity value or a maximum similarity value of the design similarity table DST[Mₛ] for the machine learning model Mₛ is calculated. Based on the average similarity value or the maximum similarity value for each of the machine learning models (e.g., M₁, . . . , or Mₖ), the machine leaning model Mₓ is selected from the multiple machine leaning models (M₁, . . . , and Mₖ). In some embodiments, the selected machine leaning model Mₓ has an average similarity value avg(DST[Mₓ]) that is larger than the average similarity value of other machine leaning models. In some embodiments, the selected machine leaning model Mₓ has a maximum similarity value max(DST[Mₓ]) that is larger than the maximum similarity value of other machine leaning models.

In some embodiments, the design similarity table between the reference design contents and the user design contents is implemented as a matrix of cosine similarities. For example, in some embodiments, the design similarity table DST[Mₛ] for the machine learning model Mₛ is implemented as a matrix of cosine similarities that has n rows and m columns, where the integer n is the number of the reference design contents associated with the design processes (e.g., T_{s,1}, . . . , or T_{s,n}) based on the machine leaning model Mₛ, and the integer m is the number of the user design contents associated with the multiple user design processes (e.g., C₁, . . . , and Cₘ). The element at the i'th row and the j'th column of the matrix is a cosine similarity cos(θ_{i,j}) between the reference design content associated with the design process T_{s,i} and the user design content associated with the user design process Cⱼ, where 1≤i≤n and 1≤j≤m. The average similarity value avg(DST[Mₛ]) of the design similarity table DST[Mₛ] is the average value of all elements in the matrix of cosine similarities, avg(DST[Mₛ])=Σ cos(θ_{i,j})/(n×m). The maximum similarity value max(DST[Mₛ]) of the design similarity table DST[Mₛ] is the maximum value of all elements in the matrix of cosine similarities, max (DST[Mₛ])=max [cos(θ_{i,j})].

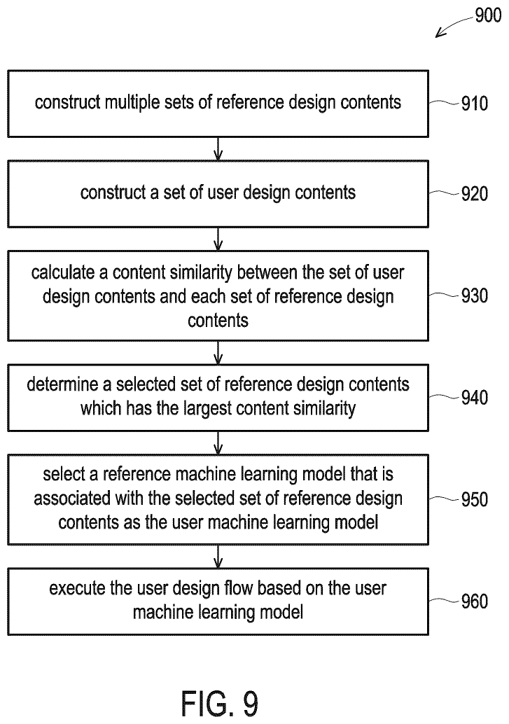

FIG. 9 is a flowchart of a method 900 of selecting one of the reference machine learning models as a user machine learning model to execute a user design flow, in accordance with some embodiments. The sequence in which the operations of method 900 are depicted in FIG. 9 is for illustration only; the operations of method 900 are capable of being executed in sequences that differ from that depicted in FIG. 9. It is understood that additional operations may be performed before, during, and/or after the method 900 depicted in FIG. 9, and that some other processes may only be briefly described herein.

In operation 910 of method 900, multiple sets of reference design contents are constructed. In some embodiments, at least one of the multiple sets of reference design contents is constructed based on one or more design recipe parameters in a reference design recipe which specifies a reference design flow executed based on a reference machine learning model. In the example embodiments as shown in FIG. 8, the design content associated with a design process (e.g., T_{1,1}, . . . , or T_{1,n}) is constructed based on one or more design recipe parameters in a reference design recipe which specifies a reference design flow executed based on the reference machine learning model M₁. The design content associated with a design process (e.g., T_{k,1}, . . . , or T_{k,n}) is constructed based on one or more design recipe parameters in a reference design recipe which specifies a reference design flow executed based on the reference machine learning model Mₖ.

In the example of FIG. 8, the design contents associated with the design processes T_{1,1}, . . . , and T_{1,n} are stored in the machine learning content database 880[1] as a first set of reference design contents. The design contents associated with the design processes T_{h,1}, . . . , and T_{k,n} are stored in the machine learning content database 880[k] as a second set of reference design contents. In some embodiments, more than two sets of reference design contents are constructed and stored in various machine learning content databases.

In operation 920 of method 900, a set of user design contents is constructed. In some embodiments, a set of user design contents is constructed based on one or more design recipe parameters in a user design recipe which specifies a user design flow executed based on a user machine learning model. In the example of FIG. 8, the set of the user design contents associated with the user design processes (C₁, . . . , and Cₘ) are stored in the user design content database 860U.

In operation 930 of method 900, a content similarity between the set of user design contents and each set of reference design contents (which is associated with a reference machine learning model) is calculated. In some embodiments, a similarity table between the set of user design contents and each set of reference design contents is calculated, and either an average similarity value or a maximum similarity value of the similarity table is calculated as the content similarity.

In operation 940 of method 900, a selected set of reference design contents which has the largest content similarity with the set of user design contents is determined. Then, in operation 950 of method 900, a reference machine learning model that is associated with the selected set of reference design contents is selected as the user machine learning model. In operation 960 of method 900, a user design flow is executed based on the user machine learning model.

In the example of FIG. 8, if the set of reference design contents for the design process (T_{1,1}, . . . , and T_{1,n}) has the largest content similarity with the set of user design contents for the user design processes (C₁, . . . , and Cₘ), then, the reference machine learning model M₁ is selected as the user machine learning model. If the set of reference design contents for the design process (T_{k,1}, . . . , and T_{k,n}) has the largest content similarity with the set of user design contents for the user design processes (C₁, . . . , and Cₘ), then, the reference machine learning model Mₖ is selected as the user machine learning model. As a general example, for 1≤x≤k, if the set of reference design contents for the design process (T_{x,1}, . . . , and T_{x,n}) has the largest content similarity with the set of user design contents for the user design processes (C₁, . . . , and Cₘ), then, the reference machine learning model Mₓ is selected as the user machine learning model. Here, the content similarity between the set of reference design contents for the design process (T_{x,1}, . . . , and T_{x,n}) and the set of user design contents is larger than a content similarity between other set of reference design contents for the design process (T_{y,1}, . . . , and T_{y,n}, with y≠x) and the set of user design contents.

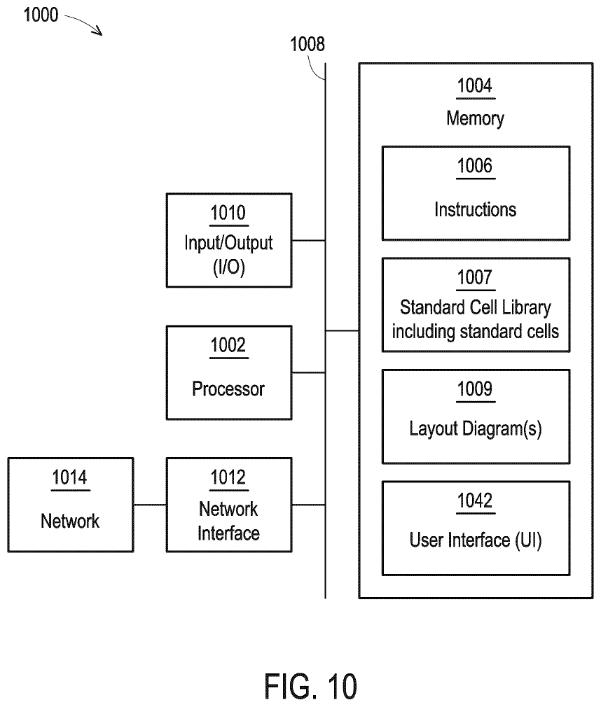

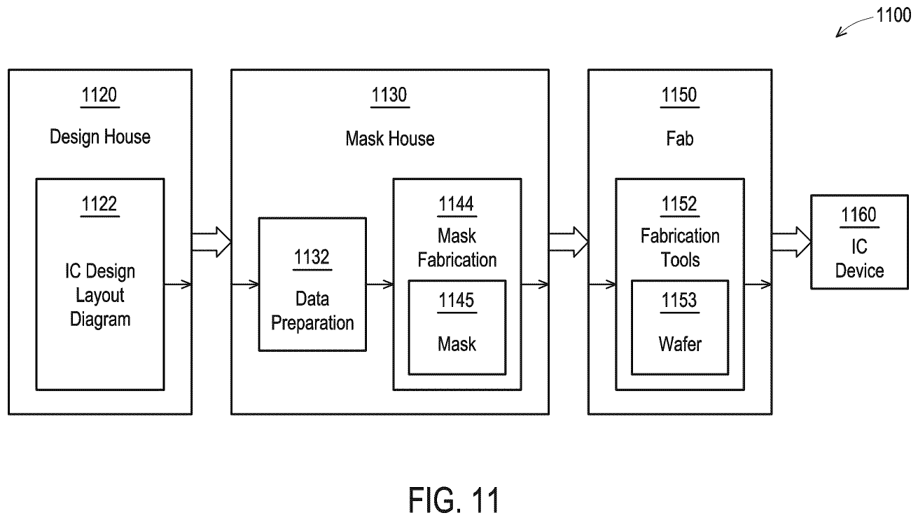

FIG. 10 is a block diagram of an electronic design automation (EDA) system 1000 in accordance with some embodiments.

In some embodiments, EDA system 1000 includes an APR system. Methods described herein of designing layout diagrams represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable storage medium 1004. Storage medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, storage medium 1004 stores computer program code 1006 configured to cause system 1000 (where such execution represents (at least in part) the EDA tool) to be usable for performing a portion or all of the noted processes and/or methods. In one or more embodiments, storage medium 1004 also stores information which facilitates performing a portion or all of the noted processes and/or methods. In one or more embodiments, storage medium 1004 stores library 1007 of standard cells including such standard cells as disclosed herein. In one or more embodiments, storage medium 1004 stores one or more layout diagrams 1009 corresponding to one or more layouts disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a UI through I/O interface 1010. The information is stored in computer-readable medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of an integrated circuit (IC) manufacturing system 1100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122. IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (“RDF”). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

An aspect of the present disclosure relates to a method. The method includes constructing a set of reference design contents associated with a set of reference design recipes. The method also includes determining a content similarity between a user design content and a reference design content taken from the set of reference design contents. The method further includes executing a design flow specified by a reference design recipe associated with the reference design content, as a result of the content similarity reaching a predetermined threshold.

Another aspect of the present disclosure relates to a non-transitory machine-readable medium having instructions stored thereon. The instructions stored on the non-transitory machine-readable medium is configured to cause a system having at least one processor to execute constructing a set of reference design contents associated with a set of reference design recipes. The instructions stored on the non-transitory machine-readable medium is also configured to cause the system to execute determining a content similarity between a user design content and a reference design content taken from the set of reference design contents, and executing a design flow specified by a reference design recipe associated with the reference design content, as a result of the content similarity reaching a predetermined threshold.

Still another aspect of the present disclosure relates to a system for manufacturing a semiconductor device. The system includes at least one processor and at least one non-transitory computer readable medium that stores computer executable code. The non-transitory computer readable storage medium, the computer program code and the at least one processor are configured to cause the system to construct a set of reference design contents associated with a set of reference design recipes. The non-transitory computer readable storage medium, the computer program code and the at least one processor are also configured to cause the system to determine a content similarity between a user design content and a reference design content taken from the set of reference design contents, and to execute a design flow specified by a reference design recipe associated with the reference design content, as a result of the content similarity reaching a predetermined threshold.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A method comprising:
constructing a set of reference design contents associated with a set of reference design recipes;
determining a content similarity between a user design content and a reference design content taken from the set of reference design contents; and
executing a design flow specified by a reference design recipe associated with the reference design content, as a result of the content similarity reaching a predetermined threshold.

2. The method of claim 1, wherein each reference design content is associated with a reference design recipe in the set of reference design recipes.

3. The method of claim 1, wherein constructing the set of reference design contents comprises:
constructing the reference design content from content parameters that include one or more design recipe parameters in the reference design recipe.

4. The method of claim 1, further comprising:
constructing the user design content from content parameters that include one or more design recipe parameters in a user design recipe.

5. The method of claim 1, wherein constructing the set of reference design contents comprises:
constructing the reference design content from a reference design flow based on one or more content parameters which specify a technology targeted by the reference design flow.

6. The method of claim 1, wherein constructing the set of reference design contents comprises:
constructing the user design content from a user design flow based on one or more content parameters which specify a technology targeted by the user design flow.

7. The method of claim 1, further comprising:
fetching the reference design content from a database.

8. The method of claim 1, wherein executing the design flow comprises:
optimizing the design flow while carrying out a machine learning session.

9. The method of claim 1, wherein executing the design flow comprises:
executing the design flow based on a reference machine learning model associated with the reference design content.

10. The method of claim 9, further comprising:
fetching the reference design content and the reference machine learning model from a database.

11. A non-transitory machine-readable medium having instructions stored thereon, instructions being configured to cause a system having at least one processor to execute:
constructing a set of reference design contents associated with a set of reference design recipes;
determining a content similarity between a user design content and a reference design content taken from the set of reference design contents; and
executing a design flow specified by a reference design recipe associated with the reference design content, as a result of the content similarity reaching a predetermined threshold.

12. The non-transitory machine-readable medium of claim 11, wherein each reference design content is associated with a reference design recipe in the set of reference design recipes.

13. The non-transitory machine-readable medium of claim 11, wherein constructing the set of reference design contents comprises:
constructing the reference design content from content parameters that include one or more design recipe parameters in the reference design recipe.

14. The non-transitory machine-readable medium of claim 11, wherein the instructions is configured to cause the system further to execute:
constructing the user design content from content parameters that include one or more design recipe parameters in a user design recipe.

15. The non-transitory machine-readable medium of claim 11, wherein constructing the set of reference design contents comprises:
constructing the reference design content from a reference design flow based on one or more content parameters which specify a technology targeted by the reference design flow.

16. The non-transitory machine-readable medium of claim 11, wherein constructing the set of reference design contents comprises:
constructing the user design content from a user design flow based on one or more content parameters which specify a technology targeted by the user design flow.

17. The non-transitory machine-readable medium of claim 11, wherein the instructions is configured to cause the system further to execute:
fetching the reference design content from a database.

18. The non-transitory machine-readable medium of claim 11, wherein executing the design flow comprises:
optimizing the design flow while carrying out a machine learning session.

19. The non-transitory machine-readable medium of claim 11, wherein executing the design flow comprises:
executing the design flow based on a reference machine learning model associated with the reference design content.

20. A system for manufacturing a semiconductor device, the system comprising:
at least one processor;
at least one non-transitory computer readable medium that stores computer executable code; and
the at least one non-transitory computer readable medium, the computer executable code and the at least one processor being configured to cause the system to:
construct a set of reference design contents associated with a set of reference design recipes,
determine a content similarity between a user design content and a reference design content taken from the set of reference design contents, and
execute a design flow specified by a reference design recipe associated with the reference design content, as a result of the content similarity reaching a predetermined threshold.
